(19) United States
(12) Patent Application Publication
(10) Pub. No.: US 2021/0193521 A1
(43) Pub. Date: Jun. 24, 2021

(54) DEVICE CHIP MANUFACTURING METHOD

(71) Applicant: DISCO CORPORATION, Tokyo (JP)

(72) Inventors: Koichi SHIGEMATSU, Tokyo (JP); Kei TANAKA, Tokyo (JP); Kenji FURUTA, Tokyo (JP)

(21) Appl. No.: 17/120,698

(22) Filed: Dec. 14, 2020

(30) Foreign Application Priority Data
Dec. 23, 2019 (JP) 2019-231554

(51) Int. Cl. H01L 21/78; H01L 23/544; H01L 21/66; H01L 21/268; H01L 21/683

(52) U.S. Cl. CPC H01L 21/78; H01L 23/544; H01L 22/20; H01L 2223/5446; H01L 21/6836; H01L 2221/68327; H01L 21/268

(57) ABSTRACT

A device chip manufacturing method includes adhering a protective member to a side of one surface of a front surface and a back surface of a workpiece including a device wafer, positioning the one surface on a lower side and holding the workpiece under suction by a holding surface, measuring the height of a lower surface and the height of an upper surface of the workpiece, applying a laser beam to the workpiece while adjusting the height of a focal point of the laser beam, to thereby form two or more modified layers at different heights inside the workpiece, and dividing the workpiece into device chips. The applying the laser beam includes forming a first modified layer on the lower surface side according to the height of the lower surface, and forming a second modified layer on the upper surface side according to the height of the upper surface.

### BACKGROUND OF THE INVENTION

### Field of the Invention

The present invention relates to a device chip manufacturing method for subjecting a device wafer to laser processing and thereafter dividing the device wafer into a plurality of device chips.

### Description of the Related Art

There has been known a method in which a plate-shaped workpiece with a plurality of streets set in a grid pattern on a front surface side and with a device formed in each of regions partitioned by the plurality of streets is processed by a laser beam and is thereafter divided (see, for example, Japanese Patent Laid-open No. 2002-192370). At the time of processing the workpiece by the laser beam, for example, first, a dicing tape is adhered to a back surface located on a side opposite to the front surface of the workpiece. Next, the back surface side of the workpiece is held by a chuck table. In this instance, the workpiece is disposed such that the front surface of the workpiece is on the upper side and the back surface is on the lower side.

Thereafter, a laser beam is applied to the workpiece from above the workpiece. In this instance, in a state in which the focal point of the laser beam is positioned inside the workpiece, the workpiece and the focal point are relatively moved along the street. Multiphoton absorption is generated at the focal point and in the vicinity thereof, and a modified region (modified layer) as a brittle region where mechanical strength is lowered is formed along the path of movement of the focal point. After the modified layers are formed along all the streets, the dicing tape is radially expanded. As a result, an external force is applied to the workpiece, cracks extend from the upper surface to the lower surface with the modified layers as start points, and the workpiece is divided along the streets. In short, the workpiece is divided into a plurality of device chips.

Incidentally, in-plane variability may be present in the thickness (height) of the workpiece. However, there has been developed a technology in which, for forming the modified layers at a uniform depth from the upper surface even in such a case, the height of the upper surface of the workpiece is preliminarily measured and a laser beam is applied while the height of the focal point is adjusted according to the results of measurement (see, for example, Japanese Patent Laid-open No. 2005-193286).

### SUMMARY OF THE INVENTION

However, even if the modified layers are formed at a substantially uniform depth relative to the upper surface, the modified layers are not necessarily formed at a substantially uniform depth relative to the lower surface. Therefore, even it is intended to divide the workpiece by expanding the dicing tape after the formation of the modified layers, the cracks may not reach the lower surface, and it may be impossible to divide the workpiece. For example, in the case where variability in thickness (height) in excess of ±10 μm relative to a predetermined reference height is present in the upper surface of the workpiece, the cracks may not reach the lower surface in a region where the height exceeds +10 μm (namely, a thick region). In this case, the workpiece cannot be divided. The present invention has been made in consideration of such a problem. It is an object of the present invention to restrain generation of defective division even when in-plane variability is present in the thickness of the workpiece.

In accordance with an aspect of the present invention, there is provided a device chip manufacturing method including an adhering step of adhering a protective member to a side of one surface of a front surface of a workpiece including a device wafer having on the front surface side a device region having a device formed in each of regions partitioned by streets and a back surface located on a side opposite to the front surface, a holding step of positioning the one surface on a lower side and holding the workpiece under suction by a holding surface of a chuck table through the protective member, a height measuring step of measuring a height of a lower surface of the workpiece along the streets, based on results of measurement of reflected light from the lower surface obtained by applying measurement light from above an upper surface located on a side opposite to the lower surface of the workpiece held by the holding surface or results of measurement of reflected light from the holding surface obtained by applying measurement light to the holding surface, and applying measurement light from above the workpiece to measure the height of the upper surface along the streets, based on results of measurement of reflected light from the upper surface, a laser processing step of applying a laser beam having such a wavelength as to be transmitted through the workpiece along the streets while adjusting the height of a focal point of the laser beam inside the workpiece according to the heights of the lower surface and the upper surface, to thereby form two or more modified layers at different heights inside the workpiece, after the height measuring step, and a dividing step of breaking the workpiece along the streets with the modified layers as start points, to thereby divide the workpiece into a plurality of device chips, after the laser processing step. The laser processing step includes a first processing step of applying the laser beam along the streets while adjusting the height of the focal point according to the height of the lower surface measured in the height measuring step, to thereby form a first modified layer on the lower surface side, and a second processing step of applying the laser beam along the streets while adjusting the height of the focal point according to the height of the upper surface measured in the height measuring step, to thereby form a second modified layer on the upper surface side.

Preferably, in the adhering step, the protective member is adhered to the front surface side, and, in the laser processing step, the laser beam is applied from the back surface side of the workpiece.

In addition, preferably, the device chip manufacturing method further includes a protective film adhering step of adhering a protective film to the side of other surface located on a side opposite to the one surface to which the protective member has been adhered, after the adhering step and before the holding step, in which in the holding step, an upper surface of the protective film is the upper surface of the workpiece, and, in the laser processing step, the laser beam is applied to the workpiece through the protective film.

The laser processing step of the device chip manufacturing method according to one aspect of the present invention includes the first processing step and the second processing step. In the first processing step, the first modified layer is formed on the lower surface side by applying the laser beam along the streets while the height of the focal point is adjusted according to the height of the lower surface of the workpiece measured in the height measuring step. Besides, in the second processing step, the second modified layer is formed on the upper surface side by applying the laser beam along the streets while the height of the focal point is adjusted according to the height of the upper surface of the workpiece measured in the height measuring step. In this way, the positions of the modified layers are adjusted according to the heights of both the lower surface and the upper surface of the workpiece, and therefore, generation of defective division can be restrained even when in-plane variability is present in the thickness of the workpiece.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1A is a perspective view of a wafer and the like;

FIG. 1B is a partial sectional view of the wafer and the like;

FIG. 2 is a perspective view of a laser processing apparatus;

FIG. 3A is a diagram for explaining a height measuring step;

FIG. 3B is a diagram for explaining reflected light;

FIG. 4A is a diagram for explaining a first processing step;

FIG. 4B is a diagram for explaining a second processing step;

FIG. 5 is a partial sectional view of the wafer after laser processing and a dicing tape;

FIG. 6A is a partly sectional side view depicting a tape expanding device;

FIG. 6B is a diagram depicting a dividing step;

FIG. 7 is a flow chart of a device chip manufacturing method according to a first embodiment;

FIG. 8A is a perspective view of the wafer and the like;

FIG. 8B is a partial sectional view of the wafer and the like;

FIG. 9 is a diagram depicting reflected light from a holding surface in a lower surface height measuring step;

FIG. 10 is a partial sectional view of the wafer and a protective film after laser processing and the dicing tape; and

FIG. 11 is a flow chart of a device chip manufacturing method according to a second embodiment.

### DETAILED DESCRIPTION OF THE PREFERRED EMBODIMENTS

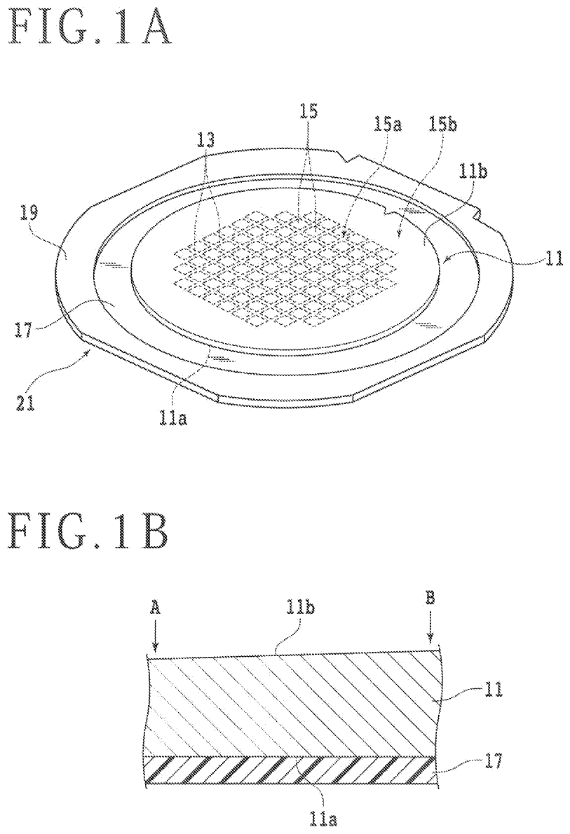

Embodiments according to modes of the present invention will be described referring to the attached drawings. First, a wafer (workpiece) 11 as an object of processing and the like will be described. FIG. 1A is a perspective view of the wafer 11 and the like, and FIG. 1B is a partial sectional view of the wafer 11 and the like. The wafer 11 in the present embodiment is a disk-shaped substrate formed from silicon (Si). It is to be noted that the wafer 11 is not limited to silicon wafer, but may be formed from a semiconductor material such as gallium arsenide (GaAs), silicon carbide (SiC), and gallium nitride (GaN), or sapphire, or any of various glasses.

A plurality of streets 13 are set in a grid pattern on a front surface 11a side of the wafer 11, and a device 15 such as an integrated circuit (IC) or a large scale integration (LSI) is formed in each of a plurality of regions partitioned by the streets 13. In other words, the wafer 11 in the present embodiment is a device wafer having a plurality of devices 15. It is to be noted that test element group (TEG) may be formed on the streets 13 in a device region 15a where the plurality of devices 15 are formed. In addition, a peripheral surplus region 15b where the devices 15 are not formed is present in the periphery of the device region 15a.

In the case where a back surface 11b located on a side opposite to the front surface 11a of the wafer 11 is taken as a reference of height, the wafer 11 has variability in the distance (thickness) from the back surface 11b to the front surface 11a (see FIG. 1B). For example, the thickness in region A depicted in FIG. 1B is thinner than the thickness in region B. The wafer 11 is processed in a state in which a dicing tape (protective member) 17 formed of a resin is adhered to the front surface 11a side, as illustrated in FIG. 1A. The dicing tape 17 has a diameter larger than that of the wafer 11, and the wafer 11 is adhered to a substantially central portion of the dicing tape 17.

The dicing tape 17 has a stacked structure of a base material layer formed of a resin such as a polyolefin, and an adhesive layer formed of a ultraviolet ray-curing resin, or the like, for example. The adhesive layer exhibits a strong sticking force to the wafer 11 and the like, and on the other hand, is cured and is lowered in the sticking force when irradiated with ultraviolet rays. It is to be noted that the dicing tape 17 may not necessarily have the stacked structure of the base material layer and the adhesive layer. The dicing tape 17 may have only the base material layer. In this case, the dicing tape 17 is adhered to the wafer 11 by thermocompression bonding, for example. One surface of an annular frame 19 formed of a metal is adhered to a peripheral portion of the dicing tape 17. As a result, the wafer 11 is supported by the frame 19 through the dicing tape 17. In the present embodiment, the unit of the wafer 11, the dicing tape 17, and the frame 19 is referred to as a wafer unit 21.

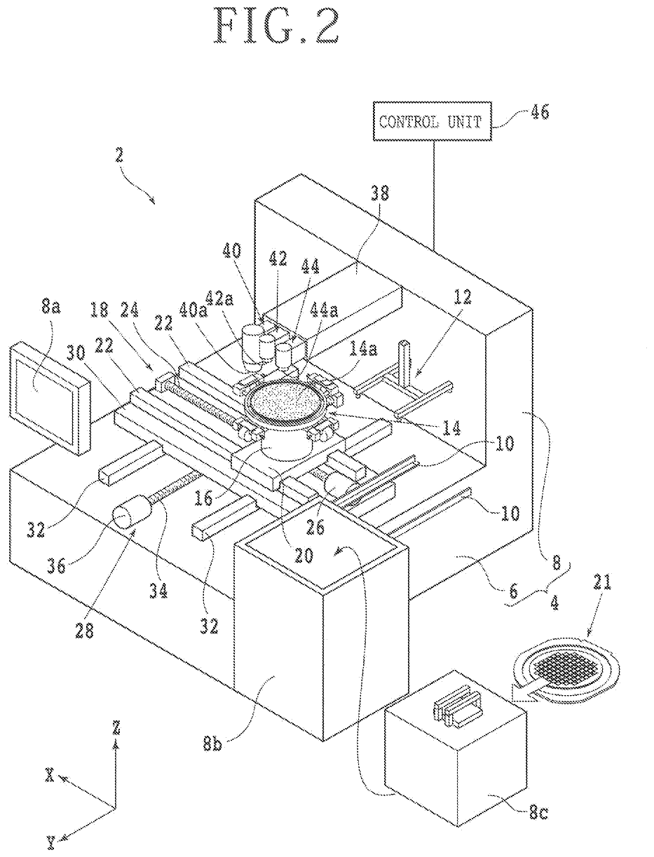

Next, a laser processing apparatus 2 for applying laser processing to the wafer 11 will be described. FIG. 2 is a perspective view of the laser processing apparatus 2. It is to be noted that in FIG. 2, a component is represented by a functional block. The laser processing apparatus 2 includes a base 4 for supporting each structure. The base 4 includes a rectangular parallelepiped base section 6, and a wall section 8 extending upward at a rear end of the base section 6. The upper side of the base section 6 is covered with a metallic cover member (not illustrated), and a touch panel 8a functioning as an input device and a display device is disposed at a side surface of the cover member located at a front end of the base section 6.

A cassette elevator 8b is provided on a right side of the laser processing apparatus 2, facing the touch panel 8a. A cassette 8c in which a plurality of wafer units 21 are accommodated is mounted on a lift base of the cassette elevator 8b. A pair of guide rails 10 are provided on a rear side of the cassette 8c. A clamp carrying mechanism (not illustrated) for drawing the wafer unit 21 from the cassette 8c onto the guide rails 10 is provided on an upper side of the pair of guide rails 10.

A carrying unit 12 is provided above the pair of guide rails 10. The carrying unit 12 carries the wafer unit 21 between the guide rails 10 and a holding table (chuck table) 14 in a state in which the frame 19 is sucked by a suction pad. The holding table 14 has a metallic frame body having a disk-shaped recess on an upper surface side. A disk-shaped porous plate formed of a porous ceramic or the like is fixed in the recess of the frame body. A flow path (not illustrated) is formed inside the frame body, and a suction source (not illustrated) such as an ejector is connected to one end of the flow path.

When a negative pressure generated by the suction source is made to act on the porous plate through the flow path, a negative pressure is generated at an upper surface of the porous plate. Therefore, the upper surface of the porous plate functions as a holding surface 14a for holding the wafer unit 21 under suction. The holding table 14 is supported in a rotatable manner by a support base 16 having a rotational drive source (not illustrated) such as a motor. In addition, the support base 16 is supported by an X-axis moving table 20 of an X-axis moving mechanism 18.

The X-axis moving table 20 is supported in the manner of being slidable in an X-axis direction by a pair of X-axis guide rails 22 substantially parallel to the X-axis direction. A nut section (not illustrated) is provided on a back surface side (lower surface side) of the X-axis moving table 20, and an X-axis ball screw 24 disposed in substantially parallel to the X-axis guide rails 22 is coupled to the nut section in a rotatable manner. An X-axis pulse motor 26 is connected to one end of the X-axis ball screw 24. When the X-axis ball screw 24 is rotated by the X-axis pulse motor 26, the X-axis moving table 20 is moved in the X-axis direction (processing feeding direction) along the X-axis guide rails 22.

A Y-axis moving mechanism 28 is provided on the back surface side (lower surface side) of the X-axis moving table 20. The Y-axis moving mechanism 28 has a Y-axis moving table 30 that supports the X-axis moving mechanism 18. The Y-axis moving table 30 is supported in the manner of being slidable in a Y-axis direction by a pair of Y-axis guide rails 32 substantially parallel to the Y-axis direction. A nut section (not illustrated) is provided on the back surface side (lower surface side) of the Y-axis moving table 30, and a Y-axis ball screw 34 disposed in substantially parallel to the Y-axis guide rails 32 is coupled to the nut section in a rotatable manner.

A Y-axis pulse motor 36 is connected to one end of the Y-axis ball screw 34. When the Y-axis ball screw 34 is rotated by the Y-axis pulse motor 36, the Y-axis moving table 30 is moved in the Y-axis direction (indexing feeding direction) along the Y-axis guide rails 32. One end of a support arm 38 extending forward is fixed to a front surface of an upper portion of the wall section 8. Part of a laser applying unit 40 is fixed to the support arm 38. The laser applying unit 40 includes a laser generating section (not illustrated).

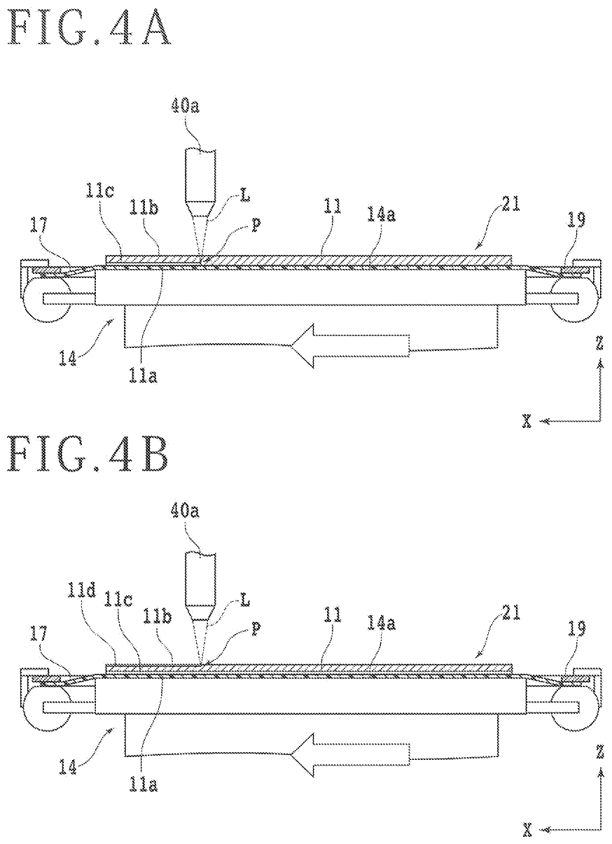

The laser generating section has a laser oscillator (not illustrated) having a laser medium such as Nd:YAG or Nd:YVO₄ suitable for laser oscillation. The laser generating section generates a pulsed laser beam L (see FIG. 4A and the like) having a predetermined wavelength (for example, 1,064 nm) such as to be transmitted through the wafer 11. A head section 40a is disposed at the other end of the support arm 38. A condenser lens (not illustrated) for concentrating the laser beam L is provided at the head section 40a. The condenser lens is disposed in such a manner that the optical axis is parallel to a Z-axis direction. The laser beam L is applied from the head section 40a toward the holding surface 14a.

An actuator (not illustrated) including a piezo element is connected to the condenser lens. By adjusting a voltage supplied to the actuator to thereby adjust the position of the condenser lens in the Z-axis direction, the position of a focal point P (see FIG. 4A and the like) of the laser beam L is adjusted. A microscope unit 42 is provided at a position adjacent to the laser applying unit 40. The microscope unit 42 images the wafer 11 held by the holding surface 14a. The microscope unit 42 has a head portion 42a in which an imaging lens (not illustrated) is disposed such as to face the holding surface 14a.

Light taken in through the imaging lens is guided to an imaging element (not illustrated) provided inside the microscope unit 42. The imaging element includes a complementary metal oxide semiconductor (CMOS) image sensor, a charge coupled device (CCD) image sensor, or the like. A height measuring instrument 44 is provided at a position adjacent to the microscope unit 42. The height measuring instrument 44 is, for example, a spectral interference type laser displacement meter, and measures the heights of the front surface 11a, the back surface 11b of the wafer 11 held by the holding surface 14a, and the like.

The laser displacement meter has a light source (not illustrated) such as a superluminescent diode (SLD). Infrared light of a wide band is emitted from the light source as inspection light. Part of the light emitted from the light source is reflected by a half-mirror (not illustrated) provided inside the head section 44a of the height measuring instrument 44, and goes toward the object of measurement such as the wafer 11. Part of the light reflected by the object of measurement is transmitted through the half-mirror, to be incident on a spectrometer (not illustrated). The spectrometer has a diffraction grating (not illustrated) for spectrally separating the incident light to obtain a spectrum. A light receiving element (not illustrated) such as a CCD is disposed in the vicinity of the diffraction grating. The light spectrally separated by the diffraction grating is converted into an electrical signal according to light intensity on a wavelength basis in the light receiving element. The light receiving element is connected to a control unit 46 which will be described later. The control unit 46 analyzes the waveform of the electrical signal outputted from the light receiving element by Fourier transformation or the like, for example.

Incidentally, a reference plate (not illustrated) serving as a reference for height measurement is provided at a lower end portion of the head section 44a. The reference plate is formed, for example, of glass, quartz, or the like. A part of the light incident on one surface (reference surface) of the reference plate is reflected by the reference surface, and other part of the light incident on the reference surface is transmitted through the reference plate and is reflected by the object of measurement. In other words, first reflected light reflected by the reference surface and second reflected light reflected by the object of measurement are incident on the spectrometer. The first reflected light and the second reflected light are intensified by each other at a predetermined wavelength according to the distance (optical distance) from the reference surface to the object of measurement. By utilizing this principle, the distance from the reference surface to a predetermined surface (for example, an upper surface, a lower surface, or the like of the workpiece) of the object of measurement is calculated by the control unit 46. In addition to the calculation of the distance, the control unit 46 controls the components of the laser processing apparatus 2.

The control unit 46 controls the cassette elevator 8b, the pair of guide rails 10, the carrying unit 12, the X-axis moving mechanism 18, the Y-axis moving mechanism 28, the laser applying unit 40, the microscope unit 42, the height measuring instrument 44, and the like. The control unit 46 includes a computer including a processing device such as, a central processing unit (CPU), a main storage device such as a dynamic random access memory (DRAM), and an auxiliary storage device such as a flash memory or a hard disk drive, for example. By operating the processing device and the like according to a software stored in the auxiliary storage device, functions of the control unit 46 are realized.

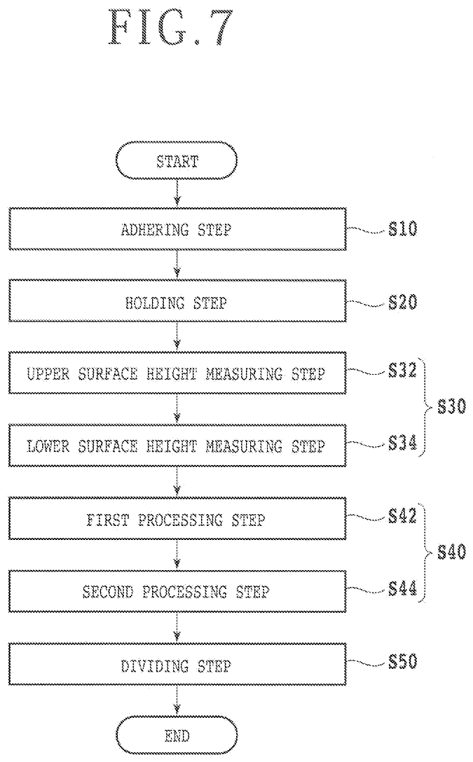

Next, a manufacturing method for the device chips 23 according to a first embodiment will be described referring to FIGS. 1A to 6B. It is to be noted that FIG. 7 is a flow chart of the manufacturing method for the device chips 23 according to the first embodiment. In the present embodiment, first, as depicted in FIG. 1A, the dicing tape 17 is adhered to the front surface 11a side of the wafer 11 and one surface of the frame 19, to form the wafer unit 21 (adhering step S10).

The adhering step S10 may be performed by a tape adhering device (not illustrated) or may be manually performed by an operator. After the adhering step S10, the cassette 8c accommodating each wafer unit 21 is mounted on the lift base of the cassette elevator 8b. Next, the wafer unit 21 is drawn out from the cassette 8c onto the guide rails 10 by a clamp carrying mechanism (not illustrated). The wafer unit 21 adjusted in the position in the X-axis direction by the pair of guide rails 10 is carried to the holding table 14 by the carrying unit 12. In this instance, the wafer unit 21 is mounted on the holding surface 14a in such a manner that the surface (in the present embodiment, the front surface 11a) with the dicing tape 17 adhered thereto is on the lower side. In other words, the front surface 11a is the lower surface of the wafer 11, and the back surface 11b is the upper surface of the wafer 11.

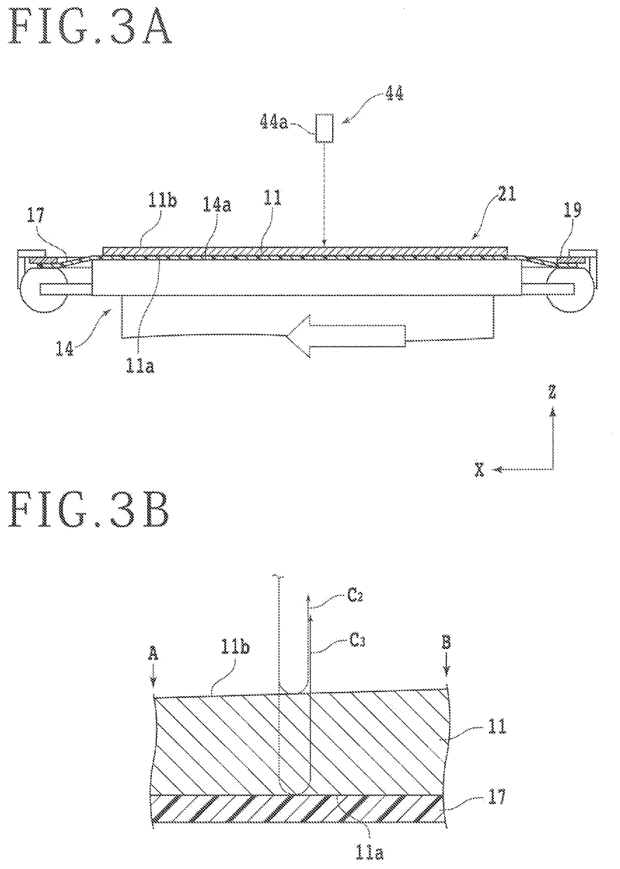

Subsequently, the suction source is operated to generate a negative pressure at the holding surface 14a. As a result, the lower surface (front surface 11a) side is held by the holding surface 14a through the dicing tape 17 (holding step S20). After the holding step S20, the height of the lower surface (front surface 11a) and the height of the upper surface (back surface 11b) are measured along the streets 13 by use of the height measuring instrument 44 or the like (height measuring step S30). FIG. 3A is a diagram for explaining the height measuring step S30.

In the height measuring step S30, first, alignment of the wafer 11 is conducted by use of the microscope unit 42 or the like. Next, a lower end of the head section 44a of the height measuring instrument 44 is positioned on an extension line of one street 13. Then, while measurement light is applied to the wafer 11 from above the wafer 11, the wafer 11 is moved along the X-axis direction relatively to the head section 44a by the X-axis moving mechanism 18. In this instance, reflected light from the wafer 11 is measured by the height measuring instrument 44.

FIG. 3B is a diagram for explaining the reflected light. In the present embodiment, results of measurement of first reflected light C₁ (not illustrated) reflected by the reference surface and second reflected light C₂ reflected by the upper surface (back surface lib) are analyzed by the control unit 46. As a result, the height of the upper surface (back surface lib) relative to the reference surface is measured (upper surface measuring step S32). Similarly, results of measurement of the first reflected light C₁ (not illustrated) reflected by the reference surface and third reflected light C₃ reflected by the lower surface (front surface 11a) are analyzed by the control unit 46. As a result, the height of the lower surface (front surface 11a) relative to the reference surface is measured (lower surface measuring step S34). It is to be noted that the height of the lower surface is not necessarily flat since ruggedness or the like of the holding surface 14a is reflected.

In this way, the height of the upper surface (back surface 11b) and the height of the lower surface (front surface 11a) are measured at once based on the results of measurement of the reflected light. After the heights of the upper surface and the lower surface are measured along one street 13, the wafer 11 is put into indexing feeding along the Y-axis direction. As a result, the head section 44a is positioned on an extension line of another street 13 adjacent to the one street 13 to which the measurement light has been applied. Then, the heights of the upper surface and the lower surface are similarly measured along another street 13.

After the heights of the upper surface and the lower surface are measured along all the streets 13 set along one direction, the rotational drive source is operated to rotate the holding table 14 by 90 degrees. Then, the heights of the upper surface and the lower surface are measured along all the streets 13 in another direction orthogonal to the one direction. XY coordinates (positions) on the upper surface and the lower surface and information concerning the heights (the heights of the upper surface and the lower surface) at each position measured in the height measuring step S30 are stored in a storage section (for example, the auxiliary storage device) of the control unit 46.

After the height measuring step S30, the laser beam L is applied to the wafer 11 from above the wafer 11 to process the wafer 11 along the streets 13 (laser processing step S40). Specifically, in a state in which the height of the focal point P of the laser beam L is positioned inside the wafer 11, the focal point P of the laser beam L and the wafer 11 are relatively moved in the X-axis direction along the street 13. As a result, a modified region (modified layer) as a brittle region where mechanical strength is lowered is formed inside the wafer 11 along the street 13. In the present embodiment, firstly, a first modified layer 11c is formed on the lower surface side of the wafer 11 (first processing step S42).

FIG. 4A is a diagram for explaining the first processing step S42. In the first processing step S42, information obtained in the height measuring step S30 is read out from the storage section, and while the height of the focal point P is adjusted according to the height of the lower surface of the wafer 11 by controlling the abovementioned actuator according to the XY coordinates, the laser beam L is applied along the street 13. It is to be noted that since the processing feeding speed of the holding table 14 at the time of applying the laser beam L is predetermined, the position of the focal point P in the Z-axis direction can be adjusted along the street 13 by operating the abovementioned actuator at a predetermined timing according to the processing feeding speed.

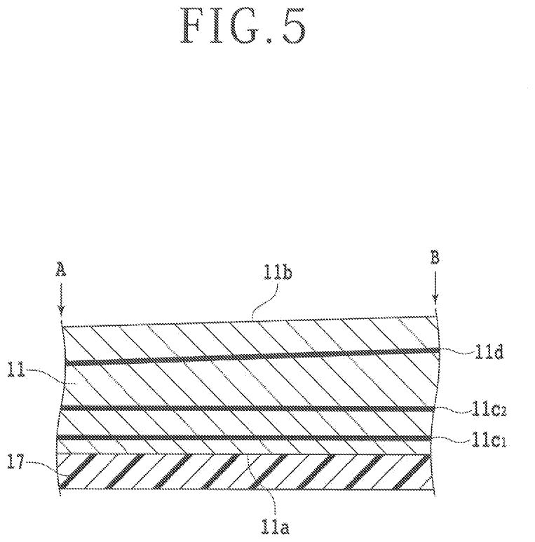

In the first processing step S42, after the laser beam L is applied along all the streets 13 along one direction, the holding table 14 is rotated by 90 degrees, and the laser beam L is applied along all the streets 13 along another direction orthogonal to the one direction. As a result, the first modified layers 11c are formed along all the streets 13. It is to be noted that in the first processing step S42 of the present embodiment, two kinds of first modified layers 11c₁ and 11c₂ are formed at different heights on the lower surface side of the wafer 11 (see FIG. 5). The first modified layers 11c₁ are formed at positions of 30 μm to 50 μm from the lower surface, whereas the first modified layers 11c₂ are formed at positions of 130 μm to 150 μm from the lower surface.

In order to avoid scattering, splashing, or the like of the laser beam L to the lower surface (front surface 11a), it is preferable to form the first modified layers 11c₂ after the first modified layers 11c₁ are formed. It is to be noted that the number of the kinds of the first modified layers 11c is not limited to two, and the number may be one or may be three or more. After the first processing step S42, second modified layers 11d are formed on the upper surface side of the wafer 11 (second processing step S44). FIG. 4B is a diagram for explaining the second processing step S44.

In the second processing step S44, also, the information is read out from the storage section, and while the height of the focal point is adjusted according to the height of the upper surface (back surface lib) by operating the actuator according to the processing feeding speed, the laser beam L is applied along the streets 13.

The second modified layers 11d are formed, for example, at positions spaced downward by a predetermined distance of 100 μm to 120 μm from the height of the upper surface. FIG. 5 is a partial sectional view of the wafer 11 after formation of the second modified layers 11d and the dicing tape 17. In the second processing step S44 of the present embodiment, one kind of second modified layers 11d are formed on the upper surface side of the wafer 11. It is to be noted that the number of kinds of the second modified layers 11d is not limited to one, and the number may be two or more. In the present embodiment, in a state in which the front surface 11a is positioned on the lower side, the laser beam L is applied from above the wafer 11. Therefore, generation of defective processing due to reflection of the laser beam L by the TEG formed on the streets 13 on the front surface 11a side can be prevented.

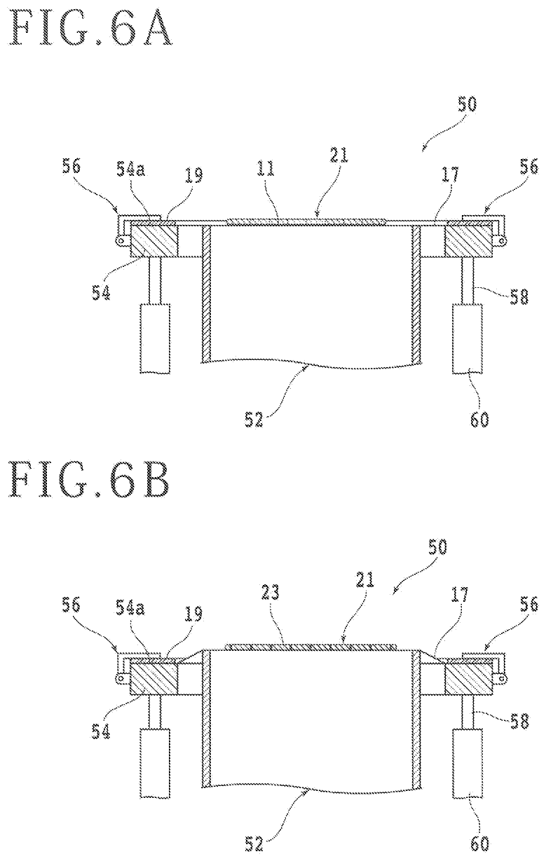

After the laser processing step S40, the wafer 11 is divided into a plurality of device chips 23 (dividing step S50). In the dividing step S50, a tape expanding device 50 is used. FIG. 6A is a partially sectional side view depicting the tape expanding device 50. The tape expanding device 50 has a cylindrical drum 52 having a diameter larger than the diameter of the wafer 11. A plurality of rollers (not illustrated) are provided at an upper end portion of the drum 52 along the circumferential direction.

An annular frame holding table 54 having an inside diameter larger than the diameter of the drum 52 is provided at a peripheral portion of the drum 52. An upper surface of the frame holding table 54 is a substantially flat mount surface 54a on which the frame 19 is mounted. A plurality of clamp unit 56 are provided at a peripheral portion of the frame holding table 54. In addition, an upper end portion of a rod 58 movable along the height direction of the drum 52 is fixed to a lower portion of the frame holding table 54.

A part on the lower side of the rod 58 is disposed inside an air cylinder 60. When the rod 58 is drawn into the air cylinder 60, the mount surface 54a is lowered relative to an upper end of the drum 52. Next, the dividing step S50 conducted using the tape expanding device 50 will be described. FIG. 6B is a diagram depicting the dividing step S50. In the dividing step S50, in a state in which the upper end of the drum 52 and the mount surface 54a are set at substantially the same height, the wafer unit 21 is mounted on the drum 52 and the mount surface 54a.

Next, the position of the frame 19 is fixed by the clamp units 56. Then, the rod 58 is drawn into the air cylinder 60, whereby the mount surface 54a is lowered relative to the upper end of the drum 52. As a result, the dicing tape 17 is radially expanded, and an external force is applied to the wafer 11. The wafer 11 is broken along the streets 13, with the first modified layers 11c and the second modified layers 11d as start points and are divided into a plurality of device chips 23. In the present embodiment, two or more kinds of modified layers including the first modified layers 11c according to the height of the lower surface and the second modified layers 11d according to the height of the upper surface are formed. In this way, the positions of the modified layers are adjusted according to the heights of both the lower surface and the upper surface, and therefore, generation of defective division can be restrained even when in-plane variability is present in the thickness of the wafer 11.

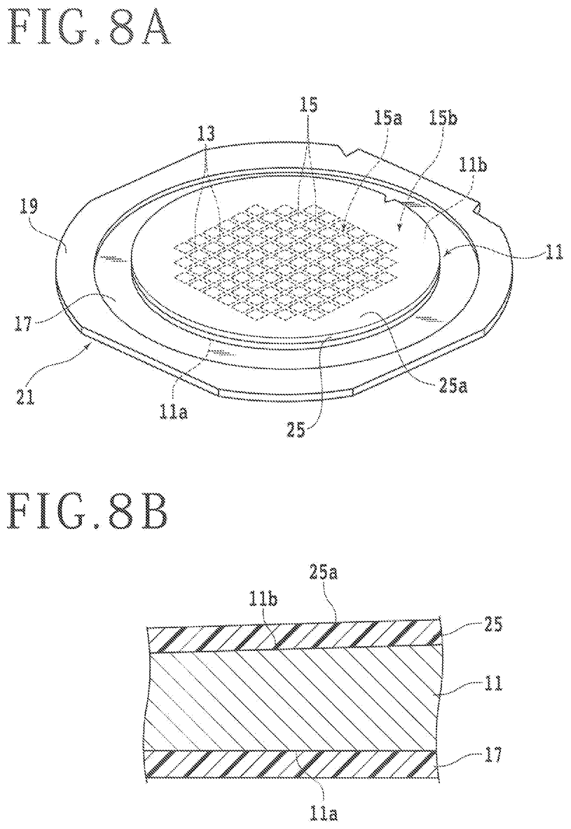

Next, a second embodiment will be described. In the second embodiment, a resin-made protective film 25 is adhered to the back surface 11b located on the side opposite to the front surface 11a to which the dicing tape 17 has been adhered. FIG. 8A is a perspective view of the wafer 11 and the like according to the second embodiment. The protective film 25 has, for example, a stacked structure of a base material layer and an adhesive layer, and the adhesive layer side is adhered to the upper surface of the wafer 11. With the protective film 25 thus provided, for example, generation of chipping (lacking) in the dividing step S50 can be reduced. FIG. 8B is a partial sectional view of the wafer 11 with the protective film 25 adhered thereto and the like.

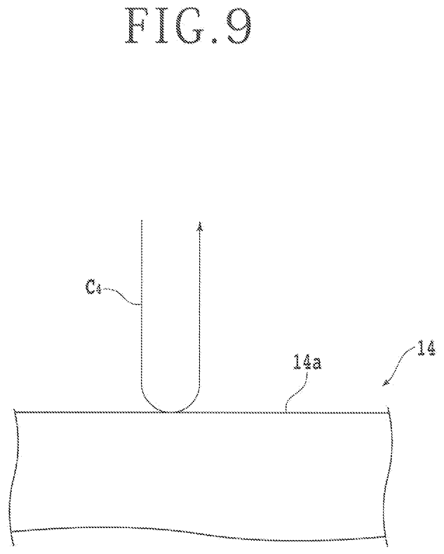

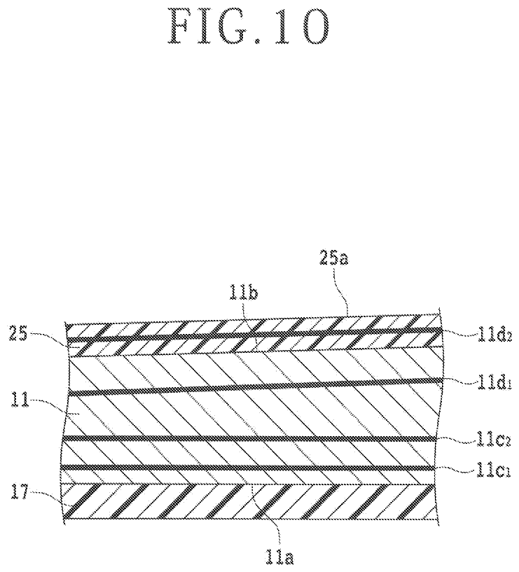

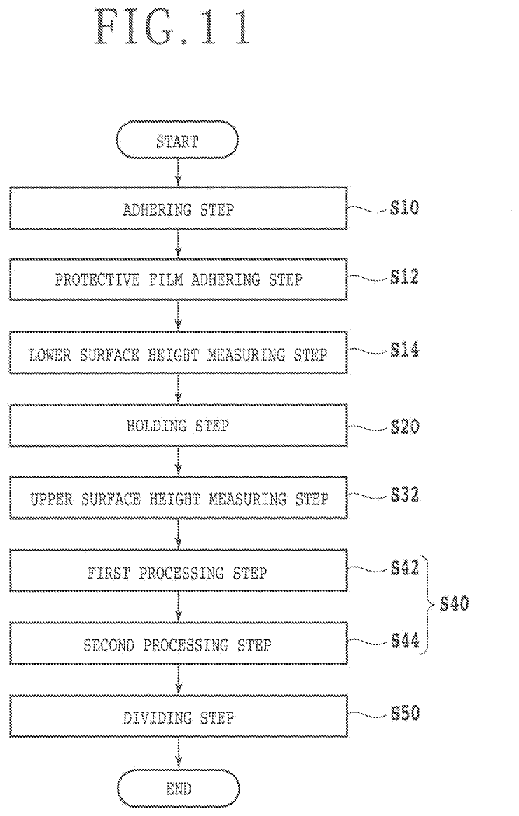

In the second embodiment, a stacked body of the wafer 11 and the protective film 25 is a workpiece to be processed by the laser beam L. In addition, in the second embodiment, the front surface 11a of the wafer 11 is a lower surface of the workpiece, whereas an upper surface 25a of the protective film 25 is an upper surface of the workpiece. Besides, one unit of the wafer 11, the dicing tape 17, the frame 19 and the protective film 25 is a wafer unit 21. Next, referring to FIGS. 9 and 10, a manufacturing method for the device chips 23 according to the second embodiment will be described. FIG. 11 is a flow chart of the manufacturing method for the device chips 23 according to the second embodiment. In the following, differences from the first embodiment will be described primarily.

In the second embodiment, after the adhering step S10, the protective film 25 is adhered to the back surface 11b side (protective film adhering step S12). Next, the height of the holding surface 14a of the holding table 14 is measured (lower surface height measuring step S14). FIG. 9 is a diagram depicting fourth reflected light C₄ from the holding surface 14a in the lower surface height measuring step S14. In the lower surface height measuring step S14, measurement light is applied from the head section 44a, and results of measurement of first reflected light C₁ (not illustrated) reflected by the reference surface of the head section 44a and fourth reflected light C₄ reflected by the holding surface 14a are analyzed by the control unit 46. As a result, the height of the holding surface 14a as a whole relative to the reference surface is measured.

Then, the thickness (for example, 100 μm) of the dicing tape 17 is added to the height of the holding surface 14a measured. As a result, the height of the lower surface (front surface 11a) relative to the reference surface is calculated. In this way, in the second embodiment, the height position of the lower surface (front surface 11a) in the case where the lower surface side is held by the holding surface 14a is measured indirectly. Note that it is sufficient for the lower surface height measuring step S14 to be conducted before the first processing step S42 and may be performed before the adhering step S10 or before the protective film adhering step S12.

The XY coordinates (positions) on the lower surface (front surface 11a) and the information concerning the height of the lower surface at each position are stored in the storage section (for example, the auxiliary storage device) of the control unit 46, as in the first embodiment. After the lower surface height measuring step S14, the holding step S20 and the upper surface height measuring step S32 are sequentially carried out. In the upper surface height measuring step S32, measurement light is applied from the head section 44a, and results of measurement of first reflected light C₁ (not illustrated) reflected by the reference surface and fifth reflected light C₅ (not illustrated) reflected by the upper surface 25a of the protective film 25 are analyzed by the control unit 46. As a result, the height of the upper surface 25a relative to the reference surface is measured.

The XY coordinates (positions) on the upper surface 25a and the information concerning the height of the upper surface 25a at each position are stored in the storage section (for example, the auxiliary storage device) of the control unit 46. Subsequently, the laser processing step S40 is sequentially conducted, as in the first embodiment. It is to be noted that in the laser processing step S40 of the second embodiment, the laser beam L is applied to the inside of the wafer 11 through the protective film 25. As a result, in the first processing step S42, the first modified layers 11c₁ and 11c₂ are formed at different positions on the lower surface (front surface 11a) side of the wafer 11.

Besides, in the second processing step S44, second modified layers 11d₁ are formed on the upper surface (back surface 11b) side of the wafer 11, and in addition, second modified layers 11d₂ are formed in the protective film 25. FIG. 10 is a partial sectional view of the wafer 11 and the protective film 25 after laser processing and the dicing tape 17. It is to be noted that at the time of forming the second modified layers 11d₁ and 11d₂, the laser beam L is applied along the streets 13 while the height of the focal point P is adjusted according to the height of the upper surface 25a of the protective film 25 (namely, the upper surface of the workpiece).

In the second embodiment, also, since the positions of the first modified layers 11c and the second modified layers 11d are adjusted according to both the lower surface and the upper surface of the workpiece (namely, the wafer 11 and the protective film 25), generation of defective division can be restrained even when in-plane variability is present in the thickness of the wafer 11 and the like. Other than the above, the structures, methods, and the like according to the above embodiment can be modified as required insofar as the modifications do not depart from the scope of the object of the present invention.

In the first and second embodiments described above, the wafer 11 and the like have been processed in a state in which the front surface 11a of the wafer 11 is positioned on the lower side and the back surface 11b is positioned on the upper side. However, the wafer 11 and the like may be processed in a state in which the back surface 11b of the wafer 11 is positioned on the lower side and the front surface 11a is positioned on the upper side. In the case where the back surface 11b is on the lower side, the dicing tape (protective member) 17 is adhered to the back surface 11b side. In addition, the protective film 25 may be adhered to the side of the front surface 11a located on the upper side, as in the second embodiment.

Incidentally, the laser processing step S40 may be conducted while the height of the workpiece is measured by the height measuring instrument 44, instead of performing the laser processing step S40 after the height of the workpiece is measured by the height measuring instrument 44. For example, in the case where the laser processing apparatus 2 is provided with one height measuring instrument 44, the laser processing step S40 is conducted using the laser applying unit 40 while the height of the workpiece is measured by the height measuring instrument 44 at the time of processing feeding toward one side in the X-axis direction. It is to be noted that, however, in the case where the height measuring instruments 44 are provided at both sides of the laser applying unit 40, the laser processing step S40 can be performed while the height of the workpiece is measured not only at the time of processing feeding toward one side in the X-axis direction but also at the time of processing feeding toward the other side in the X-axis direction.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A device chip manufacturing method comprising:
an adhering step of adhering a protective member to a side of one surface of a front surface of a workpiece including a device wafer having on the front surface side a device region having a device formed in each of regions partitioned by streets and a back surface located on a side opposite to the front surface;
a holding step of positioning the one surface on a lower side and holding the workpiece under suction by a holding surface of a chuck table through the protective member;
a height measuring step of measuring a height of a lower surface of the workpiece along the streets, based on results of measurement of reflected light from the lower surface obtained by applying measurement light from above an upper surface located on a side opposite to the lower surface of the workpiece held by the holding surface or results of measurement of reflected light from the holding surface obtained by applying measurement light to the holding surface, and applying measurement light from above the workpiece to measure the height of the upper surface along the streets, based on results of measurement of reflected light from the upper surface;
a laser processing step of applying a laser beam having such a wavelength as to be transmitted through the workpiece along the streets while adjusting the height of a focal point of the laser beam inside the workpiece according to the heights of the lower surface and the upper surface, to thereby form two or more modified layers at different heights inside the workpiece, after the height measuring step; and
a dividing step of breaking the workpiece along the streets with the modified layers as start points, to thereby divide the workpiece into a plurality of device chips, after the laser processing step,
wherein the laser processing step includes
a first processing step of applying the laser beam along the streets while adjusting the height of the focal point according to the height of the lower surface measured in the height measuring step, to thereby form a first modified layer on the lower surface side, and
a second processing step of applying the laser beam along the streets while adjusting the height of the focal point according to the height of the upper surface measured in the height measuring step, to thereby form a second modified layer on the upper surface side.

2. The device chip manufacturing method according to claim 1,
wherein in the adhering step, the protective member is adhered to the front surface side, and
in the laser processing step, the laser beam is applied from the back surface side of the workpiece.

3. The device chip manufacturing method according to claim 1, further comprising:
a protective film adhering step of adhering a protective film to the side of other surface located on a side opposite to the one surface to which the protective member has been adhered, after the adhering step and before the holding step,
wherein in the holding step, an upper surface of the protective film is the upper surface of the workpiece, and
in the laser processing step, the laser beam is applied to the workpiece through the protective film.
